(19) United States
(12) Patent Application Publication
(10) Pub. No.: US 2008/0199780 A1
(43) Pub. Date: Aug. 21, 2008

(54) ELECTROCHEMICAL ELEMENT, METHOD FOR MANUFACTURING ELECTRODE THEREOF, AND LITHIATION TREATMENT METHOD AND LITHIATION TREATMENT APPARATUS

(76) Inventors: Hiroshi HAYATA, Osaka (JP); Toshitada Sato, Osaka (JP); Kunihiko Bessho, Osaka (JP); Kazuyoshi Honda, Osaka (JP)

Correspondence Address: MCDERMOTT WILL & EMERY LLP, 600 13TH STREET, NW, WASHINGTON, DC, 20005-3096, US

(21) Appl. No.: 12/035,190

(22) Filed: Feb. 21, 2008

(30) Foreign Application Priority Data
Feb. 21, 2007 (JP) 2007-040217

(51) Int. Cl. H01M 4/38; C23C 16/06; C23C 16/00

(52) U.S. Cl. 429/231.95; 427/78; 118/715

(57) ABSTRACT

A method for manufacturing an electrode for an electrochemical element capable of absorbing and releasing lithium ions includes a lithiation treatment method for compensating an irreversible capacity of the electrode for an electrochemical element. In the lithiation treatment method, lithium is provided to the electrode by allowing a lithium vapor to flow with a movement route of the lithium vapor limited.

### BACKGROUND OF THE INVENTION

1. Field of the Invention

The present invention relates to a lithiation treatment method for providing lithium to an electrode for an electrochemical element and a manufacturing method including the lithiation treatment method, as well as an electrochemical element using the electrode treated or manufactured by using these methods and further an apparatus for lithiating the electrode for the electrochemical element. More particularly, it relates to a lithiation treatment method for providing lithium to an electrode for an electrochemical element capable of absorbing and releasing lithium ions by using a lithium vapor and a manufacturing method including the lithiation treatment method, as well as an electrochemical element using the electrode treated or manufactured by using these methods and further an apparatus for lithiating the electrode for the electrochemical element capable of absorbing and releasing lithium ions by using a lithium vapor.

2. Background Art

Recently, with the widespread use of portable and cordless electronic equipment, the expectation has been increasing for compact, lightweight and high energy density secondary batteries as a driving power source for such equipment. Furthermore, technology expansion from batteries used for such small consumer goods to large secondary batteries for electric power storages or electric vehicles has been accelerated. In such circumstances, a non-aqueous electrolyte secondary battery having high voltage and high energy density, in particular, a lithium secondary battery is expected as a power source for electronic equipment, electric power storage or an electric vehicle.

A non-aqueous electrolyte secondary battery includes a positive electrode, a negative electrode, a separator interposed therebetween and a nonaqueous electrolyte. In non-aqueous electrolyte secondary batteries that are practically used at present, as an active material for the positive electrode, lithium cobalt oxide (for example, LiCoO₂) is mainly used. Lithium cobalt oxide has a high electric potential with respect to lithium, is excellent in safety and is synthesized relatively easily. As an active material for the negative electrode, various carbon materials such as graphite are mainly used.

Graphite used as an active material for a negative electrode can absorb one lithium atom per six carbon atoms theoretically and has a theoretical capacity density of 372 mAh/g. However, by a capacity loss due to the irreversible capacity, the actual capacity density is reduced to about 310 to 330 mAh/g.

Furthermore, in the circumstances where batteries with a higher energy density are demanded, silicon (Si), tin (Sn), germanium (Ge) and oxides or alloys thereof have been expected as a negative electrode active material having a large theoretical capacity density. Among them, Si and oxide of Si have been widely studied because they are inexpensive.

However, when Si, Sn, Ge and oxides or alloys thereof, which have been studied as a negative electrode active material, absorb lithium ions, the crystalline structure thereof is changed and the volume thereof is increased. When absorption and releasing of lithium ions are repeated in the course of charging and discharging and the active material expands and contracts repeatedly, the contact failure between the active material and the current collector occurs. Consequently, the charge and discharge cycle lifetime becomes shorter. In order to address such a problem, the following proposals have been made.

For example, in order to improve the charge and discharge cycle lifetime by suppressing the contact failure between the active material and the current collector due to expansion and contraction, a method for forming a thin film of an active material on the surface of the current collector has been proposed (for example, see Japanese Patent Application Unexamined Publication No. 2002-83594). Furthermore, a method for forming a film of an active material in a columnar shape and in an inclined state on the surface of a current collector has been proposed (see, for example, Japanese Patent Application Unexamined Publication No. 2005-196970). According to these proposals, by binding an active material and a current collector to each other via a metallic bond, strong and stable current collection can be secured. In particular, in a latter case, space sufficient to absorb expansion is secured around the columnar active material. Consequently, collapse of the negative electrode itself due to the expansion and contraction of the active material can be prevented, and at the same time, pressure stress from the negative electrode to the separator and the positive electrode can be reduced. Therefore, the charge and discharge cycle characteristic can be improved effectively.

However, even if the charge and discharge cycle characteristic is improved as mentioned above, when silicon oxide (SiOx (0<x<2)) which is expected to have a high capacity density is used as the negative electrode active material, an irreversible capacity generated at the initial charge is large and actual capacity density is lowered largely from the theoretical capacity density. Herein, the irreversible capacity denotes an amount of lithium ions that can be absorbed at the initial charge of silicon oxide and that cannot be released (that is irreversible) from the silicon oxide by the subsequent discharging reaction. When a negative electrode using silicon oxide as an active material is used as it is in combination with the positive electrode, a large portion of the reversible capacity of the positive electrode (the amount of lithium ions that are absorbed in the positive electrode and can be electrochemically absorbed and released) are used as the irreversible capacity. Therefore, in order to realize a high capacity battery by using silicon oxide as an active material for a negative electrode, before a battery is configured by combining the positive electrode and the negative electrode and is charged and discharged, it is necessary to preliminary compensate the lithium ions corresponding to the irreversible capacity generated at the initial charge of silicon oxide.

Therefore, as a means for compensating lithium ions, a large number of means of providing metallic lithium to the negative electrode and allowing it to be absorbed in the negative electrode as lithium ions by a solid phase reaction have been proposed. For example, a process of vapor-depositing lithium on the surface of the negative electrode, and a process of storing the negative electrode, which has been vapor deposited with lithium, in a vacuum drying atmosphere or in an electrolytic solution have been proposed (for example, Japanese Patent Application Unexamined Publication No. 2005-38720).

However, when a film of an active material is formed by the methods described in Japanese Patent Application Unexamined Publication Nos. 2002-83594 and 2005-196970 and lithium is vapor deposited on the surface of the negative electrode as described in Japanese Patent Application Unexamined Publication No. 2005-38720, a lithium vapor is dispersed inside the vacuum chamber and lithium is vapor deposited on a device and the like that transport the negative electrode in the vacuum chamber. Therefore, an excessive amount of lithium is consumed. Alternatively, the amount of vapor deposited lithium becomes ununiform on the negative electrode. Furthermore, as the amount of lithium that is an evaporation source is reduced with the passage of time, the generation amount of lithium vapor is reduced. In order to deposit lithium uniformly over the entire surface of the negative electrode, it is necessary to refill the evaporation source lithium frequently. However, in order to refill lithium safely, at the time of vapor deposition, the lithium, which is heated to a high temperature in the vacuum chamber and whose reactivity is enhanced, is required to be cooled. The vacuum chamber be also cooled. Cooling requires a long time. As a result, the productivity is extremely deteriorated.

### SUMMARY OF THE INVENTION

A method for manufacturing an electrode for an electrochemical element in accordance with the present invention includes a lithiation treatment method mentioned below. Herein, the lithiation treatment denotes treatment of allowing an electrode to absorb lithium ions. That is to say, an electrode for an electrochemical element capable of electrochemically absorbing and releasing lithium ions is subjected to lithiation treatment. In the lithiation treatment method in accordance with the present invention, lithium is provided to the electrode by allowing a lithium vapor to flow with a movement route of the lithium vapor limited.

### BRIEF DESCRIPTION OF THE DRAWINGS

FIG. 1 is a longitudinal sectional view showing a non-aqueous electrolyte secondary battery in accordance with an embodiment of the present invention.

FIG. 2 is a schematic configuration view showing an apparatus used for manufacturing a negative electrode including an active material having an inclined columnar structure in accordance with an embodiment of the present invention.

FIG. 3 is a schematic sectional view showing a negative electrode including an active material produced by using the apparatus shown in FIG. 2.

FIG. 4 is an entire configuration view showing a vacuum vapor deposition apparatus for providing lithium in accordance with an embodiment of the present invention.

FIG. 5 is a conceptual sectional view showing a configuration of a lithium vapor deposition nozzle in accordance with an embodiment of the present invention.

FIGS. 6A to 6C are graphs showing changes over time of the deposition rate of lithium, the flow rate of argon gas, and the surface position of lithium in a copper crucible, respectively, in accordance with an embodiment of the present invention.

FIG. 7 is a top plan view showing a lithium vapor deposition nozzle in a lithium vapor deposition apparatus in accordance with an embodiment of the present invention.

FIG. 8 is a sectional view showing another lithium vapor deposition nozzle in a lithium vapor deposition apparatus in accordance with an embodiment of the present invention.

### DETAILED DESCRIPTION OF THE INVENTION

Hereinafter, the embodiments of the present invention are described with reference to drawings in which a non-aqueous electrolyte secondary battery is employed as an example of an electrochemical element and a negative electrode is employed as an example of an electrode. Note here that the present invention is not limited to contents described below as long as it is based on basic features described in this specification.

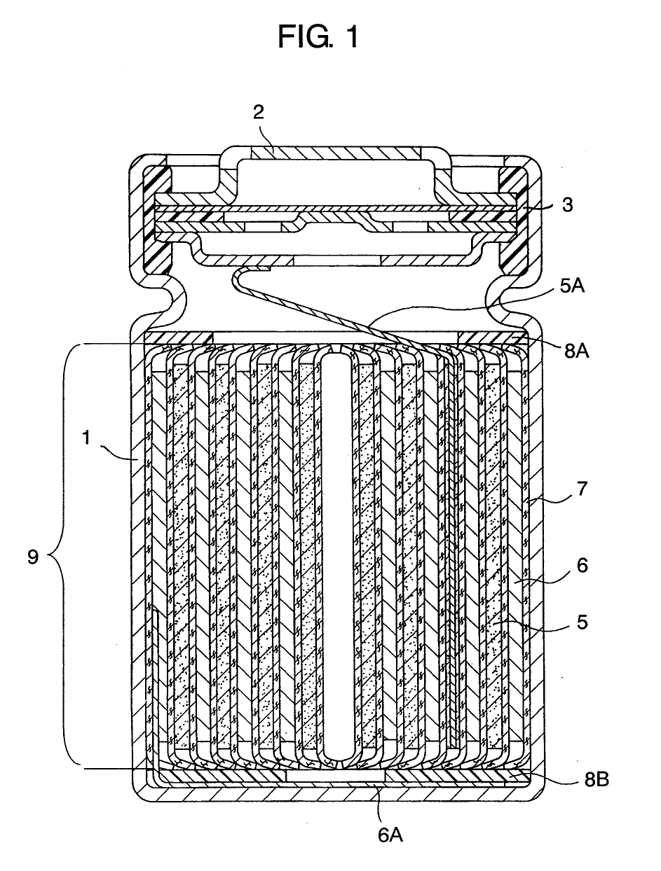

FIG. 1 is a longitudinal sectional view showing a non-aqueous electrolyte secondary battery in accordance with an embodiment of the present invention. Herein, a cylindrical battery is described as an example. This non-aqueous electrolyte secondary battery includes case 1 and electrode group 9 accommodated in case 1. Case 1 is made of metal such as stainless steel, nickel-plated iron, or the like. Electrode group 9 is produced by winding negative electrode 6 as a first electrode and positive electrode 5 as a second electrode via separator 7 in a spiral shape. Upper insulating plate 8A is disposed at the upper part of electrode group 9, and lower insulating plate 8B is disposed at the lower part of electrode group 9. An opening end of case 1 is sealed with sealing plate 2 via gasket 3. One end of positive electrode lead 5A made of aluminum is attached to positive electrode 5. Another end of positive electrode lead 5A is coupled to sealing plate 2 that also serves as a positive terminal. One end of negative electrode lead 6A made of nickel is attached to negative electrode 6. Another end of negative electrode lead 6A is coupled to case 1 that also serves as a negative electrode terminal. Electrode group 9 is impregnated with a non-aqueous electrolyte (not shown) serving as an electrolyte. That is to say, a non-aqueous electrolyte is interposed between positive electrode 5 and negative electrode 6.

In general, positive electrode 5 includes a positive current collector and a positive electrode mixture supported thereby. The positive electrode mixture may include a binder, a conductive agent, and the like, in addition to a positive electrode active material. Positive electrode 5 is produced by, for example, coating and drying a positive electrode mixture slurry including a positive electrode active material as a main component on a positive current collector.

As the positive electrode active material, lithium composite metallic oxide can be used. An example thereof includes LiₓCoO₂, LiₓNiO₂, LiₓMnO₂, LiₓCo_{y}M_{1-y}O_{z}, LiₓNi_{1-y}M_{y}O_{z}, LiₓMn₂O₄, LiₓMn_{2-z}M_{z}O₄, LiMPO₄, and Li₂MPO₄F. Herein, M denotes at least one selected from Na, Mg, Sc, Y, Mn, Fe, Co, Ni, Cu, Zn, Al, Cr, Pb, Sb and B, and 0≦x≦1.2 0≦y≦0.9 and 0≦z≦1.9 are satisfied. Note here that the value x representing the molar ratio of lithium is a value after lithium composite metallic oxide is produced and before a positive electrode is produced. The value x is increased and decreased by charge and discharge. A part of the constituent elements of these lithium composite metallic oxides may be substituted by a different kind of element. Furthermore, the surface of the lithium composite metallic oxides may be treated with metallic oxide, lithium oxide, a conductive agent, and the like. Furthermore, the surface of the lithium composite metallic oxides may be subjected to hydrophobic treatment.

An example of the binder of the positive electrode mixture may include polyvinylidene-fluoride (PVDF), polytetrafluoroethylene, polyethylene, polypropylene, aramid resin, polyamide, polyimide, polyamide-imide, polyacrylonitrile, polyacrylic acid, polymethylacrylate, polyethylacrylate, polyhexylacrylate, polymethacrylic acid, polymethylmethacrylate, polyethylmethacrylate, polyhexylmethacrylate, polyvinyl acetate, polyvinylpyrrolidone, polyether, polyethersulfone, hexafluoropolypropylene, styrene-butadiene rubber, carboxymethylcellulose, and the like. Furthermore, a copolymer of two or more kinds of compounds selected from tetrafluoroethylene, hexafluoroethylene, hexafluoropropylene, perfluoro-alkylvinyl ether, vinylidenefluoride, chlorotrifluoroethylene, ethylene, propylene, pentafluoropropylene, fluoromethylvinyl ether, acrylic acid, and hexadiene, may be used singly or in a combination of two or more thereof.

An example of the conductive agent may include graphites including natural graphites and artificial graphites; carbon blacks such as acetylene black, Ketjen black, channel black, furnace black, lampblack and thermal black; conductive fibers such as carbon fiber and metal fiber; metal powders such as aluminum powder; conductive whiskers of zinc oxide, potassium titanate, and the like; conductive metal oxide such as titanium oxide; an organic conductive material such as phenylene derivatives, and the like.

It is desirable to blend 80 to 97 wt. % of positive electrode active material, 1 to 20 wt. % of conductive agent and 2 to 7 wt. % of binder.

As the positive current collector, a porous or non-porous conductive substrate is used. An example of materials to be used for the conductive substrate may include stainless steel, aluminum, titanium, and the like. The thickness of the current collector is not particularly limited. However, the thickness is preferably in the range from 1 to 500 μm, and more preferably in the range from 5 to 20 μm. When the thickness of the current collector is in the above-mentioned range, the weight of the electrode can be reduced while the electrode keeps an adequate strength.

For separator 7, microporous thin film, woven fabric, non-woven fabric, and the like, having a high ionic permeability and also having a predetermined mechanical strength and insulating property are used. As materials for separator 7, for example, polyolefin such as polypropylene and polyethylene is preferable from the viewpoint of safety of a battery because it is excellent in durability and has a shutdown function. The thickness of separator 7 is generally in the range of 10 to 300 μm and preferably 40 μm or less. Furthermore, more preferably, it is in the range of 5 to 30 μm, and further preferably in the range of 10 to 25 μm. Furthermore, the microporous thin film may be a single layer film consisting of one kind of material or may be a composite film or a multi-layer film consisting of two or more kinds of materials. Furthermore, it is preferable that the porosity of separator 7 is in the range of 30 to 70%. Herein, the porosity means the area ratio of pores occupying the surface area of separator 7. The more preferable porosity of separator 7 is in the range of 35 to 60%.

As the non-aqueous electrolyte, liquid state, gel state, and solid state (polymer solid electrolyte) non-aqueous electrolytes can be used. The liquid state non-aqueous electrolyte (non-aqueous electrolytic solution) can be obtained by dissolving an electrolyte (for example, lithium salt) in a non-aqueous solvent. The gel state non-aqueous electrolyte is composed of a liquid-state non-aqueous electrolyte and a polymer material holding the liquid state non-aqueous electrolyte. As the polymer material, for example, PVDF, polyacrylonitrile, polyethylene oxide, polyvinyl chloride, polyacrylate, polyvinylidene fluoride hexafluoropropylene, and the like, can be used.

As the non-aqueous solvent, a well-known non-aqueous solvent can be used. The kind of the non-aqueous solvent is not particularly limited. For example, cyclic carbonate ester, chain carbonate ester, cyclic carboxylate ester, and the like, can be used. An example of cyclic carbonate ester may include propylene carbonate (PC), ethylene carbonate (EC), and the like. An example of chain carbonate ester may include diethyl carbonate (DEC), ethyl methyl carbonate (EMC), dimethyl carbonate (DMC), and the like. An example of cyclic carboxylate ester may include γ-butyrolactone (GBL), γ-valerolactone (GVL), and the like. The non-aqueous solvent may be used singly or may be in a combination of two or more thereof.

An example of the solute to be solved in a non-aqueous solvent may include LiClO₄, LiBF₄, LiPF₆, LiAlCl₄, LiSbF₆, LiSCN, LiCF₃SO₃, LiCF₃CO₂, LiAsF₆, lower aliphatic lithium carboxylate, LiCl, LiBr, LiI, chloroborane lithium, borates, imide salts, and the like. An example of borates may include lithium bis(1,2-benzenedioleate(2-)-O,O′) borate, lithium bis(2,3-naphthalene dioleate(2-)-O,O′) borate, lithium bis(2,2′-biphenyldioleate(2-)-O,O′) borate, lithium bis(5-fluoro-2-oleate-1-benzenesulfonate-O,O′) borate, and the like. An example of imide salts may include lithium bistrifluoromethanesulfonate imide ((CF₃SO₂)₂NLi), lithium trifluoromethanesulfonate nonafluorobutanesulfonate imide (LiN(CF₃SO₂)(C₄F₉SO₂)), lithium bispentafluoroethanesulfonate imide ((C₂F₅SO₂)₂NLi), and the like. The solute may be used singly or may be used in a combination of two or more thereof.

Furthermore, the non-aqueous electrolyte may include an additive that is decomposed on negative electrode 6 and is capable of forming a coated film having high conductivity with respect to lithium ions and increasing the charge and discharge efficiency. An example of the additive having such a function may include vinylene carbonate, 4-methyl vinylene carbonate, 4,5-dimethyl vinylene carbonate, 4-ethyl vinylene carbonate, 4,5-diethyl vinylene carbonate, 4-propyl vinylene carbonate, 4,5-dipropyl vinylene carbonate, 4-phenyl vinylene carbonate, 4,5-diphenyl vinylene carbonate, vinyl ethylene carbonate, divinyl ethylene carbonate, and the like. These may be used singly or in a combination of two or more thereof. Among them, at least one selected from vinylene carbonate, vinyl ethylene carbonate, and divinyl ethylene carbonate is preferable. Note here that a part of hydrogen atoms of these compounds may be substituted by a fluorine atom. It is desirable that the amount of the additive to be solved in the non-aqueous electrolytic solution is 0.1 wt. % or more and 15 wt. % or less.

Furthermore, the non-aqueous electrolyte may contain a well-known benzene derivative that is decomposed at the time of overcharging and forms a coated film on positive electrode 5 so as to inactivate a battery. As such a benzene derivative, one having a phenyl group and a cyclic compound group neighboring to this phenyl group is preferred. As the cyclic compound group, a phenyl group, a cyclic ether group, a cyclic ester group, a cycloalkyl group, a phenoxy group, and the like, are preferred. A specific example of the benzene derivative may include cyclohexylbenzene, biphenyl, diphenyl ether, and the like. These may be used singly or may be in a combination of two or more thereof. However, it is desirable that the content of the benzene derivative is 10 volume % or less with respect to the entire non-aqueous solvent.

Next, negative electrode 6 and a method for manufacturing the same are described. Negative electrode 6 includes a current collector, and an active material layer provided on the surface of the current collector and being capable of electrochemically absorbing and releasing lithium ions. For the active material layer, in addition to a carbon material, a material such as silicon (Si) and tin (Sn) capable of absorbing and releasing a large quantity of lithium ions can be used effectively as an active material. It is preferable that the ratio A/B of volume A of the material capable of absorbing and releasing a large quantity of lithium ions in a discharged state to volume B of the material in a charged state is 1.2 or more. The volumes are determined by, for example, measuring the thickness before and after charging. A material satisfying such a ratio A/B can efficiently exert the effect of the present invention regardless of whether the material is any form of an elemental substance, an alloy, a compound, a solid solution and a composite material such as a silicon-containing material or a tin-containing material. An example of the silicon-containing material may include Si and SiOx (0<x<2) or an alloy, a compound or a solid solution thereof obtained by substituting a part of Si by at least one element selected from B, Mg, Ni, Ti, Mo, Co, Ca, Cr, Cu, Fe, Mn, Nb, Ta, V, W, Zn, C, N, and Sn. As the tin-containing material, Ni₂Sn₄, Mg₂Sn and SnOₓ (0<x<2), SnO₂, SnSiO₃, LiSnO, and the like, can be used. Among them, SiOx in which the constituting ratio of Si to oxygen is further limited (0.3<x<1.3) is preferred because the discharge capacity density is large and the expansion rate at the time of charging is smaller than that of Si elemental substance. All these materials may be used singly or in a combination of two or more thereof.

An example of an active material using two or more materials in combination may include an active material layer that contains a plurality of compounds selected from a compound containing Si, oxygen and nitrogen and a plurality of compounds containing Si and oxygen at different constituting ratio of Si and oxygen.

These materials are used as an active material powder and are mixed with a binder and a conductive agent. Then, the mixture is coated on the current collector, followed by drying and rolling thereof. Thus, an active material layer can be formed. Alternatively, by using these materials, an active material thin film may be formed on the current collector by a technique such as a vacuum vapor deposition method, a sputtering method, and a CVD method. In particular, the foregoing technique for forming an active material thin film is preferred because an excellent current collection can be secured and an excellent charge and discharge cycle characteristic can be obtained when a material having a high capacity and having large expansion and contraction is used for an active material.

For the current collector, a metal foil such as stainless steel, nickel, copper, titanium, and the like, a thin film of carbon or conductive resin, and the like, may be used. In addition, a current collector that is preliminary subjected to a surface treatment with carbon, nickel, titanium, and the like, may be used. Similar to the case of the positive electrode, the thickness of the current collector is not particularly limited, but it is preferably in the range of 1 to 500 μm and more preferably in the range of 5 to 20 μm. When the thickness of the current collector falls within the above-mentioned range, the weight of the electrode can be reduced while the electrode keeps an adequate strength.

Hereinafter, a procedure for producing an active material layer that contains silicon oxide (SiOx (0<x<2)) as an active material is described as an example, in which an electrolytic copper foil is used as a current collector. Firstly, the electrolytic copper foil as the current collector is attached and fixed to a water-cooling roller disposed in a vacuum vapor deposition apparatus (not shown). A graphite crucible that contains high purity Si is disposed right underneath the water-cooling roller. After the pressure inside the vacuum vapor deposition apparatus is reduced, Si in the graphite crucible is heated with an electron beam, thereby vacuum-vapor-depositing (accumulating) Si on the current collector. At the time of vapor deposition, a small amount of oxygen is introduced into the vacuum vapor deposition apparatus from an oxygen nozzle. After the vapor deposition on one surface of the current collector is finished, the rear side (a surface that has not vapor deposited) is similarly subjected to vapor deposition. A thin film (active material layer) containing silicon oxide (SiOx (0<x<2)) as an active material is formed on both surfaces. Thus, a stip of negative electrode 6 is produced.

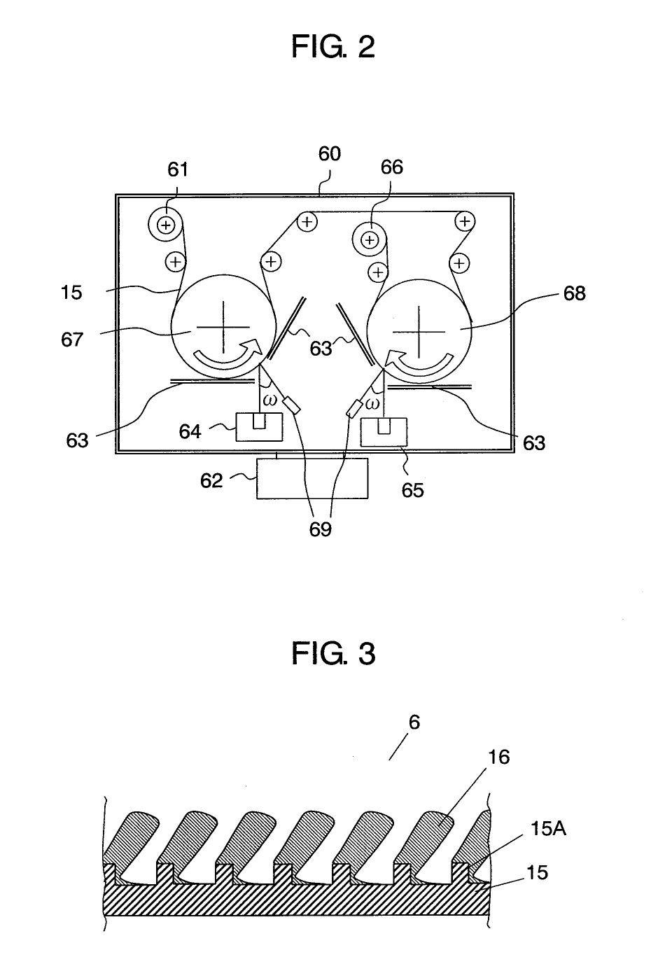

Next, a method for forming a preferable embodiment of an active material layer is described with reference to FIGS. 2 and 3. FIG. 2 is a schematic configuration view showing an apparatus used for manufacturing a negative electrode that contains an active material having an inclined columnar structure in accordance with the embodiment of the present invention. FIG. 3 is a schematic sectional view showing a negative electrode that contains an active material produced by using the apparatus shown in FIG. 2.

In the apparatus shown in FIG. 2, current collector 15 is forwarded from winding-out roll 61 to winding-up roll 66 by way of film-formation rolls 67 and 68. These rolls and vapor deposition units 64 and 65 are placed in vacuum chamber 60. The pressure inside vacuum chamber 60 is reduced by vacuum pump 62. Each of vapor deposition units 64 and 65 is composed of a vapor deposition source, a crucible and an electron beam generator.

As shown in FIG. 3, current collector 15 has a large number of protrusions 15A on the surface thereof. For example, a 30 μm-thick electrolytic copper foil having concavity and convexity (the average surface roughness of Ra=2.0 μm) by electrolytic plating is used as current collector 15. Protrusions 15A are provided on both surfaces of current collector 15, but only one surface is shown in FIG. 3 for simplification.

The inside of vacuum chamber 60 is made to be an atmosphere of a low-pressure inactive gas, for example, an atmosphere of an argon gas with a pressure of 3.5 Pa. At the time of vapor deposition, the vapor deposition source is irradiated with an electron beam generated by the electron beam generator. As the vapor deposition source, for example, Si is used. The shape of an opening portion of mask 63 is adjusted so that Si vapor is not vertically incident on the surface of current collector 15.

Current collector 15 is forwared from winding-out roll 61 to winding-up roll 66 while Si vapor is supplied to the surface of current collector 15. At the same time, oxygen is introduced into vacuum chamber 60 from oxygen nozzle 69 that is provided at an angle of ω with respect to the incident direction of Si vapor. Thereby, active material lump 16 of silicon oxide is generated on protrusion 15A of current collector 15. For example, angle ω is set to 65° and oxygen gas with a purity of 99.7% is introduced from nozzle 69 into vacuum chamber 60, and thus a 21 μm-thick film is formed on protrusion 15A of current collector 15 at the deposition speed of about 20 nm/sec. This film is made of columnar active material lump 16 of SiO_{0.4}. After active material lump 16 is formed on one surface by film-formation roll 67, current collector 15 is forwarded to film-formation roll 68, and active material lump 16 can be formed on the other surface of current collector 15 by the same method. In this way, negative electrode 6 is produced.

Note here that heat resistant tapes may be attached in equal intervals on both surfaces of current collector 15 in advance and these tapes are detached after the film is formed. Thereby, in the current collector, can be formed exposed portions to which negative electrode lead 6A is welded.

In addition to the above-mentioned method, by the methods described in Japanese Patent Application Unexamined Publication Nos. 2003-17040 and 2002-279974, negative electrode 6 having current collector 15 and a plurality of columnar active material lumps 16 provided on the surface of current collector 15 may be produced. However, it is preferable that active material lump 16 is formed in a way in which it is inclined with respect to the surface of current collector 15. By inclining active material lump 16 with respect to the surface of current collector 15 in this way, the charge and discharge cycle characteristic of the negative electrode can be improved. The reason therefor is not clear, but one of the reasons is thought to be as follows. The active material having a lithium ion absorbing property is expanded and contracted when it absorbs and releases lithium ions. Stress accompanyied by the expansion and contraction is dispersed in the parallel direction and the vertical direction to the surface of current collector 15 in the negative electrode that has active material lump 16 inclining with respect to current collector 15. In this way, the generation of wrinkle of current collector 15 and exfoliation of active material lump 16 are suppressed, so that the charge and discharge cycle characteristic is thought to be improved.

It is preferable that negative electrode 6 including an active material layer made of SiOₓ produced by any of the above-mentioned methods is introduced into an atmosphere furface (not shown) and subjected to heat treatment under a predetermined temperature condition. At this time, it is further preferable that the heat treatment is carried out at a nonoxidative atmosphere. Furthermore, it is preferable that the heat treatment temperature is 100° C. or more and 900° C. or less.

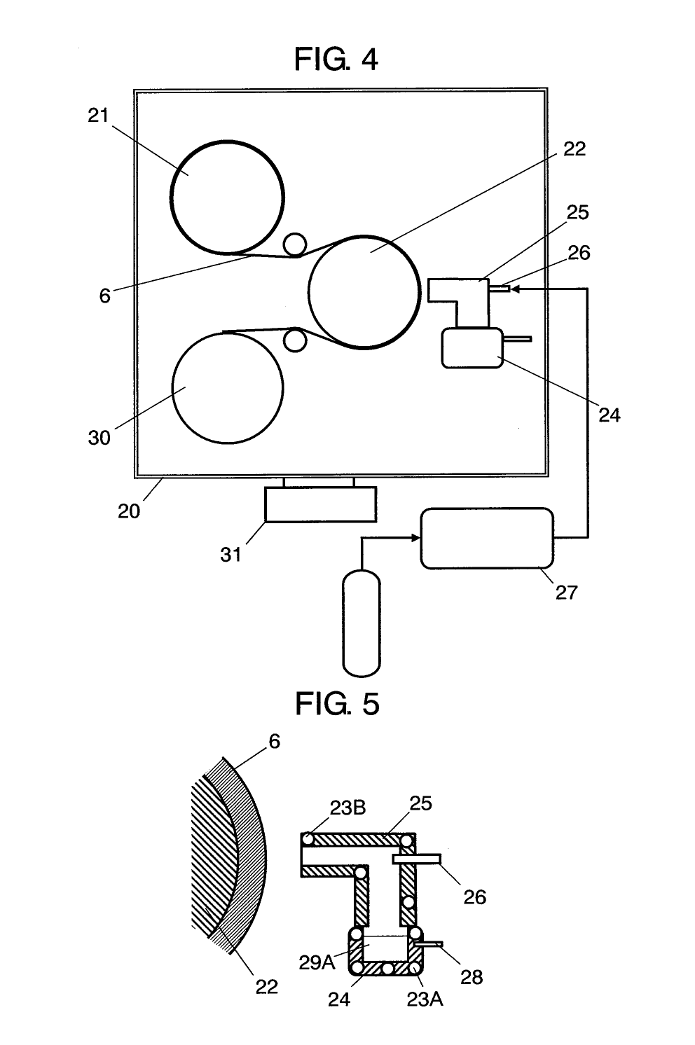

Next, a procedure for providing lithium to an active material layer of negative electrode 6 is described with reference to FIGS. 4 and 5. FIG. 4 is an entire configuration view showing a vacuum vapor deposition apparatus for providing lithium to negative electrode 6 in accordance with an embodiment of the present invention. FIG. 5 is a conceptual sectional view showing a configuration of a lithium vapor deposition nozzle in accordance with an embodiment of the present invention. The vacuum vapor deposition apparatus includes copper crucible 24 into which rod heater 23A as a heating section is incorporated, lithium vapor deposition nozzle 25, vacuum chamber 20 and vacuum pump 31. Lithium vapor deposition nozzle 25 limits the movement route of lithium vapor generated in copper crucible 24, thereby allowing the lithium vapor to flow toward the negative electrode. Vacuum chamber 20 accommodates negative electrode 6, a heating portion and lithium vapor deposition nozzle 25. This apparatus further includes gas nozzle 26 and gas flow controller 27. Gas nozzle 26 opens toward the inside of lithium vapor deposition nozzle 25 and is provided in order to allow a gas to flow into the lithium vapor. Vacuum pump 31 reduces the pressure inside vacuum chamber 20.

As shown in FIG. 4, negative electrode 6 is disposed so that it can be forwarded from winding-out roll 21 to winding-up roll 30 via cooling CAN 22 that is cooled to, for example, 20° C. in vacuum chamber 20. Metallic lithium is placed in copper crucible 24 into which rod heater 23A is incorporated. Lithium vapor deposition nozzle 25 into which rod heater 23B is incorporated is attached to copper crucible 24. Next, the pressure inside vacuum chamber 20 is reduced to, for example, 3×10⁻³ Pa. That is to say, the pressure of the atmosphere enclosing negative electrode 6 and an evaporation source of lithium is reduced. Then, electricity is applied to rod heater 23A so as to heat lithium 29A in copper crucible 24, thereby generating a lithium vapor. It is preferable that electricity is also applied to rod heater 23B so as to heat lithium vapor deposition nozzle 25 in order to prevent the generated lithium vapor from being cooled and depositing inside lithium vapor deposition nozzle 25. The temperatures of copper crucible 24 and lithium vapor deposition nozzle 25 are controlled to be, for example, 580° C. by monitoring with thermocouple 28. Herein, lithium vapor deposition nozzle 25 limits the movement route of a lithium vapor. The lithium vapor flows toward negative electrode 6 from lithium vapor deposition nozzle 25, so that lithium is provided to an active material layer of negative electrode 6. By limiting the movement route of the lithium vapor generated in copper crucible 24 with the use of lithium vapor deposition nozzle 25, the loss of lithium, that is, lithium scattering before it reaches the active material layer is suppressed, and lithium can be provided to the active material layer efficiently.

It is preferable that before lithium vapor starts to be generated, an argon gas is started to flow into the inside of lithium vapor deposition nozzle 25 from gas nozzle 26 provided opening inside of lithium vapor deposition nozzle 25. The flow rate of argon gas to be flown is set to, for example, 100 sccm.

After lithium is deposited on the active material layer on one surface of electrode 6 while negative electrode 6 is forwarded from winding-out roll 21 to winding-up roll 30 at a rate of 0.2 m/min, lithium is deposited similarly on the rear side of the active material layer. Instead of an argon gas, other noble gas, hydrogen or a mixture gas thereof may be allowed to flow. Thus, when at least one gas selected from a noble gas, a hydrogen gas and a mixture gas thereof is allowed to flow into lithium vapor deposition nozzle 25 for limiting the movement route of a lithium vapor, as compared with the case where the gas is not allowed to flow, the movement amount of the lithium vapor can be limited more efficiently. Thus, even if a large amount of lithium is used as an evaporation source, lithium can be uniformly provided on the entire surface of the active material layer of negative electrode 6.

Furthermore, it is preferable that the flow rate of argon gas is gradually reduced with the passage of time by using gas flow controller 27. For example, the flow rate of argon gas is reduced at, for example, 0.05 sccm/min.

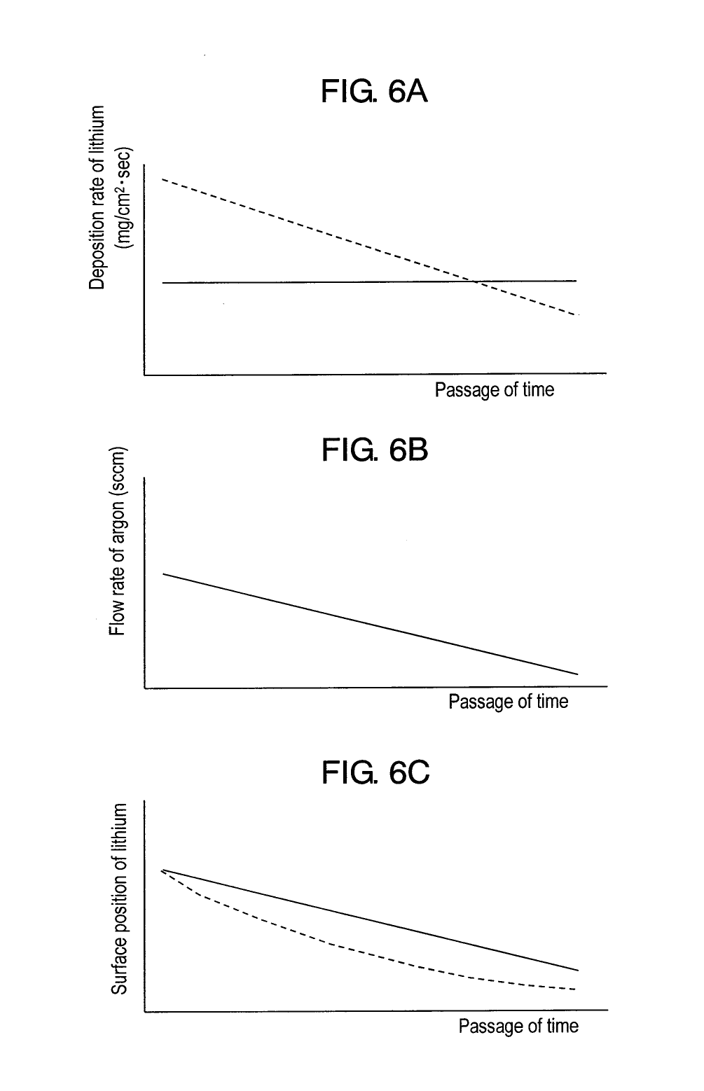

FIGS. 6A to 6C are graphs schematically showing the changes over time of the deposition rate of lithium, the flow rate of argon gas, and the surface position of lithium 29A in copper crucible 24, respectively, in accordance with the embodiment of the present invention. Broken lines show the changes over time when argon gas is not allowed to flow. As shown in FIG. 6A, when argon gas is not allowed to flow, as the amount of lithium in the evaporation source is reduced with the passage of time, the deposition rate of lithium is accordingly reduced. This is because the surface position of lithium is reduced as shown in FIG. 6C, so that conductance with respect to lithium vapor is reduced, and that the movement amount is reduced.

On the other hand, as shown by solid lines, when an argon gas is allowed to flow into the flow of the lithium vapor from gas nozzle 26, the movement amount of lithium vapor is limited. As compared with the case where argon gas is not allowed to flow (shown by a broken line), the deposition rate of lithium is reduced at the starting time of vapor deposition. After the vapor deposition is started, when the flow amount of argon gas is gradually reduced with the passage of time as shown in FIG. 6B, the limitation on the movement amount of lithium vapor is accordingly weakened. As a result, as shown by a solid line of FIG. 6A, the deposition rate of lithium can be kept substantially constant. Thus, regardless of the time passage, it is possible to provide lithium to the entire surface of negative electrode 6 uniformly. That it to say, by gradually reducing the flow rate of gas with the passage of time, even if the amount of lithium in the evaporation source is lowered as the passage of the time, the deposition rate of lithium can be kept substantially constant. Therefore, it is possible to provide lithium on the entire surface of negative electrode 6 uniformly and efficiently.

Note here that gas nozzle 26 is provided so that argon gas is allowed to flow in the direction parallel to the flow of the lithium vapor in vapor deposition nozzle 25 (direction of parallel current flow). However, gas nozzle 26 may be provided so that argon gas is allowed to flow toward lithium 29A heated. The flow rate of argon gas may not be changed linearly as shown in FIG. 6B. The flow rate of argon gas may be gradually reduced according to the size of copper crucible 24 and lithium vapor deposition nozzle 25, and the amount of lithium vapor-deposited on negative electrode 6. The control of the flow rate of argon gas can be carried out efficiently, for example, by using a relation between the flow rate of argon gas and the deposition rate of lithium, which is determined by carrying out vapor deposition of lithium with the use of a smooth current collector instead of negative electrode 6. Alternatively, inside the apparatus, the film thicknesses before and after the vapor deposition of lithium are measured by using a laser displacement gauge or a contact displacement gauge. Then, the flow rate of argon gas is controlled from the difference between the measured film thicknesses. Thereby, more precise processing can be carried out. Furthermore, the gas flowing from gas nozzle 26 is not limited to argon gas. Other noble gases that do not react with lithium vapor, hydrogen, or a mixture gas thereof may be used.

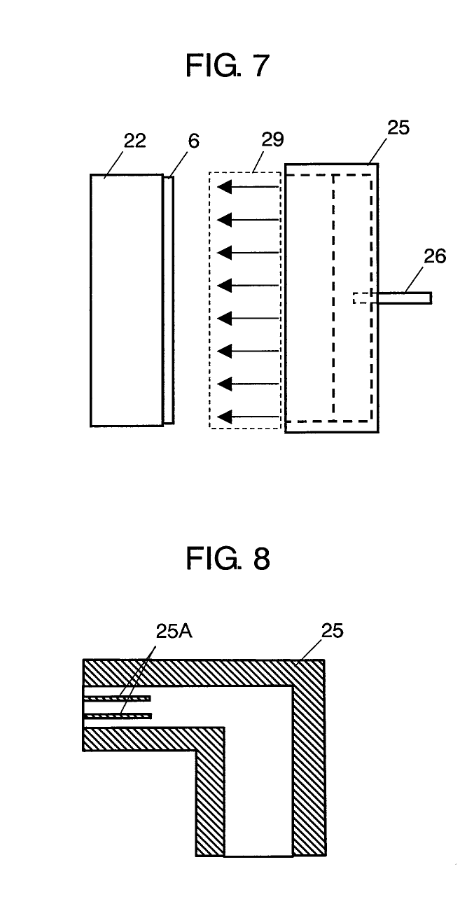

Next, a preferable position in which gas nozzle 26 is provided is described. FIG. 7 is a top plan view showing lithium vapor deposition nozzle 25 disposed in a lithium vapor deposition apparatus in accordance with an embodiment of the present invention.

When the width of negative electrode 6 is wide, lithium vapor deposition nozzle 25 for allowing lithium vapor to flow toward negative electrode 6 is also required to be widened. However, if the width of lithium vapor deposition nozzle 25 is increased, a larger amount of lithium vapor flows in the central part of lithium vapor deposition nozzle 25 as compared with the peripheral part. Then, as shown in FIG. 7, gas nozzle 26 is provided in lithium vapor deposition nozzle 25 so that gas flows in the central part of the lithium vapor. Specifically, for example, gas nozzle 26 is provided in the center in the width direction of lithium vapor nozzle 25. Thus, it is possible to suppress the movement amount of lithium vapor 29 in the central part of lithium vapor deposition nozzle 25. As a result, lithium vapor 29 can flow uniformly in the width direction of lithium vapor deposition nozzle 25, and therefore, it is possible to provide lithium to negative electrode 6 uniformly in the width direction.

Next, another preferable structure of lithium vapor deposition nozzle 25 is described. FIG. 8 is a sectional view showing another lithium vapor deposition nozzle 25 in a lithium vapor deposition apparatus in accordance with an embodiment of the present invention. As shown in FIG. 8, rectifying plate 25A may be provided at the side of an exhaust hole of lithium vapor deposition nozzle 25 so as to further limit the movement route of the lithium vapor. The flow of the lithium vapor limited by lithium vapor deposition nozzle 25 is rectified by rectifying plate 25A, thereby desirably reducing the dispersing range of the lithium vapor. Furthermore, the same effect can be obtained by reducing the width of the exhaust hole of lithium vapor deposition nozzle 25 in the vertical direction.

In the above-mentioned embodiments, a cylindrical battery is used as an example. However, the same effect can be obtained by using, for example, a rectangular-shaped battery. Furthermore, in the above-mentioned embodiments, a non-aqueous electrolyte secondary battery is used as an example, but the present invention can apply to an electrochemical element such as a capacitor as long as the electrochemical element uses a lithium ion as a charge carrier and at least one of the electrodes has an irreversible capacity.

As mentioned above, in the manufacturing method of the present invention, an electrochemical element using a electrode having a lithiation treatment has a high capacity and a long lifetime. Therefore, a non-aqueous electrolytic solution secondary battery that is one kind of the electrochemical elements is useful as a driving power source of electronic equipment such as a notebook-sized personal computer, a portable telephone and a digital still camera, and furthermore, a power source for an electric power storage requiring high power or a power source of an electric vehicle. The present invention provides a very important and effective means because it can improve the productivity in manufacturing the above-mentioned electrochemical element.

What is claimed is:

1. A method for manufacturing an electrode for an electrochemical element capable of electrochemically absorbing and releasing a lithium ion, the method comprising:
forming an active material layer of the electrode; and
providing lithium to the electrode by allowing a lithium vapor to flow with a movement route of the lithium vapor limited.

2. The method for manufacturing an electrode for an electrochemical element according to claim 1, wherein the movement route of the lithium vapor is limited by allowing at least one gas selected from a noble gas, a hydrogen gas and a mixture gas thereof to flow into the lithium vapor so as to limit a movement amount of the lithium vapor.

3. The method for manufacturing an electrode for an electrochemical element according to claim 2, wherein a flow rate of the gas is gradually reduced with a passage of time.

4. The method for manufacturing an electrode for an electrochemical element according to claim 2, wherein the gas is allowed to flow into a central part of a flow of the lithium vapor.

5. The method for manufacturing an electrode for an electrochemical element according to claim 1, wherein the lithium vapor is generated by reducing a pressure of an atmosphere enclosing an evaporation source of lithium and the electrode, and heating the evaporation source of lithium.

6. A lithiation treatment method for an electrode for an electrochemical element capable of electrochemically absorbing and releasing a lithium ion, the method comprising:
limiting a movement route of a lithium vapor; and
providing lithium to the electrode by treating the electrode with the lithium vapor.

7. The lithiation treatment method for an electrode for an electrochemical element according to claim 6, wherein the movement route of the lithium vapor is limited by allowing at least one gas selected from a noble gas, a hydrogen gas and a mixture gas thereof to flow into the lithium vapor so as to limit a movement amount of the lithium vapor.

8. The lithiation treatment method for an electrode for an electrochemical element according to claim 7, wherein a flow rate of the gas is gradually reduced with a passage of time.

9. The lithiation treatment method for an electrode for an electrochemical element according to claim 7, wherein the gas is allowed to flow into a central part of a flow of the lithium vapor.

10. The lithiation treatment method for an electrode for an electrochemical element according to claim 6, wherein the lithium vapor is generated by reducing a pressure of an atmosphere enclosing an evaporation source of lithium and the electrode and heating the evaporation source of lithium.

11. An electrochemical element comprising:
a first electrode capable of electrochemically absorbing and releasing a lithium ion, the electrode being treated with a lithium vapor with a movement route of the lithium vapor limited so as to be provided with lithium;
a second electrode capable of electrochemically absorbing and releasing a lithium ion; and
an electrolyte interposed between the first electrode and the second electrode.

12. An apparatus for lithiation treatment of an electrode for an electrochemical element capable of electrochemically absorbing and releasing a lithium ion, comprising:
a lithium vapor deposition nozzle allowing a lithium vapor to flow with a movement route of the lithium vapor limited so as to provide lithium to a surface of the electrode; and
a chamber for accommodating the electrode and the lithium vapor deposition nozzle.

13. The apparatus for lithiation treatment according to claim 12, further comprising a gas nozzle for allowing at least one gas selected from a noble gas, a hydrogen gas and a mixture gas thereof to flow into the lithium vapor.

14. The apparatus for lithiation treatment according to claim 13, further comprising a gas flow controller for gradually reducing a flow rate of the gas with a passage of time.

15. The apparatus for lithiation treatment according to claim 13, wherein the gas nozzle is provided in the lithium vapor deposition nozzle so that the gas flows into a central part of the lithium vapor.

16. The apparatus for lithiation treatment according to claim 12, further comprising:
a heating section provided in the chamber and heating an evaporation source of lithium so as to generate the lithium vapor; and
a vacuum pump for reducing a pressure inside the chamber.
